(19) United States
(12) Patent Application Publication
(10) Pub. No.: US 2024/0355919 A1
(43) Pub. Date: Oct. 24, 2024

(54) GROUP III NITRIDE MULTILAYERED STRUCTURE AND HIGH ELECTRON MOBILITY TRANSISTOR

(71) Applicant: SUMITOMO CHEMICAL COMPANY, LIMITED, Tokyo (JP)

(72) Inventors: Taiki YAMAMOTO, Hitachi-shi (JP); Hiroyuki TOMIOKA, Hitachi-shi (JP)

(73) Assignee: SUMITOMO CHEMICAL COMPANY, LIMITED, Tokyo (JP)

(21) Appl. No.: 18/626,914

(22) Filed: Apr. 4, 2024

(30) Foreign Application Priority Data
Apr. 24, 2023 (JP) 2023-070705

(51) Int. Cl. H01L 29/778; H01L 29/20; H01L 29/36

(52) U.S. Cl. CPC H01L 29/7786; H01L 29/2003; H01L 29/36

(57) ABSTRACT

There is provided a group III nitride multilayered structure, including: a first layer comprising a group III nitride; a second layer disposed on the first layer and comprising a group III nitride containing In; and a third layer disposed on the second layer and comprising a group III nitride, wherein the first layer contains an impurity that makes the group III nitride electrically highly resistive at least in a near-interfacial region, which is a region with a thickness of 50 nm from an interface between the first layer and the second layer, a concentration of the impurity is lower on a third layer side than on a first layer side interposing the second layer therebetween, and in the third layer, the concentration of the impurity reaches less than 2×10¹⁵ cm⁻³ continuously over a thickness of at least 3 nm, so that the third layer is substantially free of the impurity.

### TECHNICAL FIELD

The present invention relates to a group III nitride multilayered structure and a high electron mobility transistor.

### DESCRIPTION OF RELATED ART

Impurities (for example, iron) are added to the group III nitride (for example, gallium nitride) to increase electrical resistance (see, for example, Patent Literature 1). It is preferable to provide a technique that can suppress the diffusion of the impurities from a layer containing impurities that increase electrical resistance, to other layers in the multilayered structure of the group III nitride, from a viewpoint of improving the controllability of the electrical characteristics of the multilayered structure.
Patent Literature 1: Japanese Patent Application Publication No. 2018-199601

### SUMMARY OF THE INVENTION

One object of the present invention is to provide a technique that can suppress a diffusion of impurities from a layer containing impurities that increase electrical resistance, to other layers in a multilayered structure of a group III nitride.

According to an aspect of the present invention, there is provided a group III nitride multilayered structure, including:
a first layer comprising a group III nitride;
a second layer disposed on the first layer and comprising a group III nitride containing In; and
a third layer disposed on the second layer and comprising a group III nitride,
wherein the first layer contains an impurity that makes the group III nitride electrically highly resistive at least in a near-interfacial region, which is a region with a thickness of 50 nm from an interface between the first layer and the second layer,
a concentration of the impurity is lower on a third layer side than on a first layer side interposing the second layer therebetween, and
in the third layer, the concentration of the impurity reaches less than 2×10¹⁵ cm⁻³ continuously over a thickness of at least 3 nm, so that the third layer is substantially free of the impurity.

There is provided a technique that can suppress a diffusion of impurities from a layer containing impurities that increase electrical resistance, to other layers in a multilayered structure of a group III nitride.

### BRIEF DESCRIPTION OF THE DRAWINGS

FIG. 1 is a schematic cross-sectional view illustrating an example of a multilayered structure according to an embodiment of the present invention.

FIG. 2 is an overall SIMS profile of a sample according to a first example of an embodiment.

FIG. 3 is a partial SIMS profile of a sample according to the first example of the embodiment.

FIG. 4 is an overall SIMS profile of a sample according to a second example of the embodiment.

FIG. 5 is a partial SIMS profile of a sample of the second example of the embodiment.

FIG. 6 is an overall SIMS profile of a sample according to a comparative embodiment.

FIG. 7 is a partial SIMS profile of a sample according to a comparative embodiment.

FIG. 8A is a graph plotting a relationship between an In composition of a diffusion suppressing layer and a Fe concentration in the samples of the embodiment and the comparative embodiment, and shows a sample in which a designed value of a doping peak concentration C1 is 1×10¹⁷ cm⁻³. FIG. 8B is a graph plotting a relationship between the In composition of the diffusion suppressing layer and the Fe concentration in the samples of the embodiment and the comparative embodiment, and shows a sample in which a designed value of the doping peak concentration C1 is 1×10¹⁸ cm⁻³.

FIG. 9 is a SIMS profile showing an In content distribution of a diffusion suppressing layer in which a designed In composition is 15.6% and a designed thickness is 2 nm.

FIG. 10A is a graph plotting a relationship between the In composition of the diffusion suppressing layer and a sheet resistance in HEMT, and FIG. 10B is a graph plotting a relationship between the In composition of the diffusion suppressing layer and a threshold voltage in HEMT.

### DETAILED DESCRIPTION OF THE INVENTION

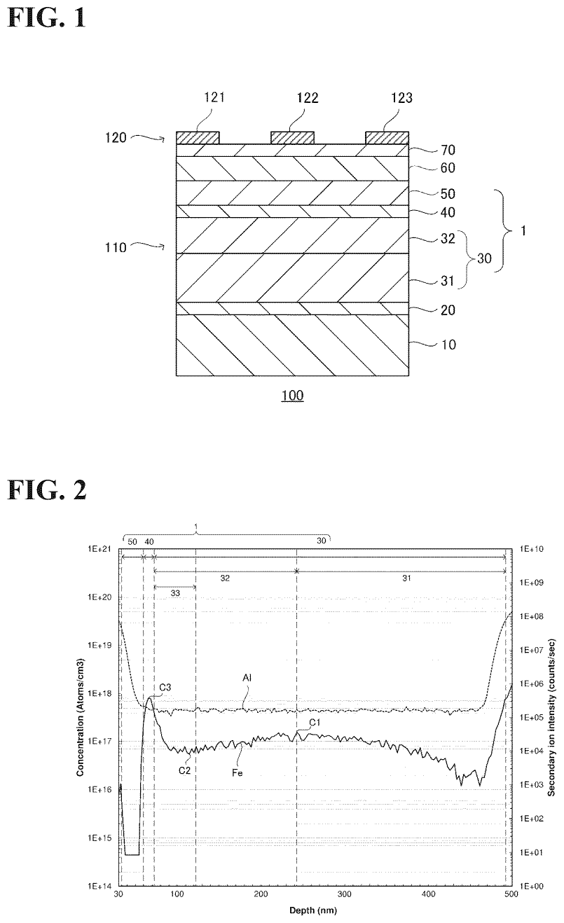

A group III nitride multilayered structure 100 (hereinafter referred to as a multilayered structure 100) according to an embodiment of the present invention will be described. FIG. 1 is a schematic cross-sectional view illustrating an example of the multilayered structure 100. The multilayered structure 100 is characterized in that it includes a diffusion suppressing part 1 configured as a lamination of three III-nitride layers. The diffusion suppressing part 1 will be described in detail later.

The multilayered structure 100 may be in the form of a semiconductor wafer including the diffusion suppressing part 1 or may also be in the form of a semiconductor element in which other members (electrodes, etc.) are further provided on the semiconductor wafer. Here, a high electron mobility transistor (HEMT) is illustrated as one embodiment of the multilayered structure 100. Hereinafter, the multilayered structure 100 will also be referred to as HEMT 100.

HEMT 100 includes a wafer 110 and an electrode 120. The wafer 110 includes a substrate 10, a nucleation layer 20, a buffer layer 30, a diffusion suppressing layer 40, a channel layer 50, a barrier layer 60, and a cap layer 70. The electrode 120 is disposed on the cap layer 70 and includes a source electrode 121, a gate electrode 122, and a drain electrode 123.

The Substrate 10 is, for example, a silicon carbide (SiC) substrate. A lamination of III-nitride layers from the nucleation layer 20 to the cap layer 70 is formed on a substrate 10. The nucleation layer 20 is disposed on the substrate 10 and comprises, for example, aluminum nitride (AlN). The buffer layer 30 is disposed on nucleation layer 20 and comprises, for example, gallium nitride (GaN). The diffusion suppressing layer 40 is disposed on the buffer layer 30 and comprises, for example, indium gallium nitride (InGaN). The channel layer 50 is disposed on the diffusion suppressing layer 40 and comprises, for example, GaN. The barrier layer 60 is disposed on the channel layer 50 and comprises, for example, aluminum gallium nitride (AlGaN). The cap layer 70 is disposed on the barrier layer 60 and comprises, for example, GaN.

The HEMT 100 according to the present embodiment is characterized in that it includes a diffusion suppressing part 1 configured as a laminated layer of the buffer layer 30, the diffusion suppressing layer 40, and the channel layer 50. The buffer layer 30, the diffusion suppressing layer 40, and the channel layer 50 are examples of the first layer, the second layer, and the third layer, which are three group III nitride layers constituting the diffusion suppressing part 1, respectively.

The buffer layer 30 contains impurity (referred to as high-resistance impurity hereinafter) that makes the group III nitride electrically highly resistive at least in a near-interfacial region 33 (see the explanation regarding FIGS. 2 to 7 below) which is a region 50 nm thick from the interface with the diffusion suppressing layer 40. Preferably, a transition metal is used as the high-resistance impurity, and examples of the transition metal include iron (Fe) and manganese (Mn). The buffer layer 30 is divided into a buffer lower layer 31 and a buffer upper layer 32, as will be described in detail later.

The diffusion suppressing layer 40 is a layer that is disposed on the buffer layer 30 (directly on the buffer layer 30) and suppresses diffusion of the high-resistance impurity from the buffer layer 30 to the channel layer 50. That is, the high-resistance impurity concentration is lower on the channel layer 50 side than on the buffer layer 30 side interposing the diffusion suppressing layer 40 therebetween. The diffusion suppressing layer 40 comprises a group III nitride containing indium (In). The inventor of the present invention considers that, as one way of thinking, the diffusion suppressing layer 40 comprises a group III nitride containing In having a larger lattice constant than the group III nitride constituting the buffer layer 30, and has a function of suppressing the diffusion of the high-resistance impurity present in the channel layer 50 by receiving a compressive strain from the buffer layer 30.

The channel layer 50 is disposed on the diffusion suppressing layer 40 (directly on the diffusion suppressing layer 40), that is, disposed on the buffer layer 30 interposing the diffusion suppressing layer 40 therebetween. Therefore, this layer is a layer substantially free of high-resistance impurity. The definition of the layer substantially free of high-resistance impurity will be described later.

In the HEMT 100 according to this embodiment, two-dimensional electron gas (2DEG) is generated near the interface with the barrier layer 60 in the channel layer 50, and the 2DEG functions as a HEMT channel. Since the channel layer 50 is substantially free of high-resistance impurity, for example, variations in sheet resistance and variations in threshold voltage caused by the high-resistance impurity, can be suppressed.

A method for manufacturing the HEMT 100 will be exemplary described. For example, a SiC substrate is prepared as the substrate 10. Each layer 20 to 70 comprising a group III nitride is epitaxially grown above the substrate 10 by, for example, metal organic vapor phase epitaxy (MOVPE). For example, Fe is added to the buffer layer 30 as a high-resistance impurity.

Among the group III source gases, trimethylaluminum (Al(CH₃)₃, TMA) gas is used as aluminum (Al) source gas, for example. Among the group III source gases, trimethylgallium (Ga(CH₃)₃, TMG) gas is used as gallium (Ga) source gas, for example. Among the group III source gases, trimethylindium (In(CH₃)₃, TMI) gas is used as the indium (In) source gas, for example. For example, Fe(C₂H₅)₂ (Cp₂Fe) gas is used as Fe-doping source gas. For example, ammonia (NH₃) is used as nitrogen (N) source gas, which is the group V source gas. For example, at least one of nitrogen gas (N₂ gas) and hydrogen gas (H₂ gas) is used as the carrier gas.

A growth temperature can be selected, for example, in a range of 700° C. to 1400° C., and a V/III ratio, which is a flow rate ratio of the group V source gas to the group III source gas, can be selected in a range of 10 to 5,000, for example. The ratio of a supply amount of each source gas is adjusted according to a composition of each layer to be formed. The thickness of each layer to be formed can be controlled by a growth time, for example, by calculating the growth time corresponding to a designed thickness from the growth rate obtained in a preliminary experiment.

The nucleation layer 20 is formed on the substrate 10 by, for example, growing an AlN layer to a designed thickness of 6 nm or more and 40 nm or less. The buffer layer 30 is formed on the nucleation layer 20 by, for example, growing a GaN layer to a designed thickness of 400 nm or more and 3000 nm or less.

The buffer lower layer 31 is formed by growing GaN from the vicinity of the lower surface of the buffer layer 30 to an intermediate thickness while supplying Fe-doping source gas. The buffer upper layer 32 is formed by growing GaN from the intermediate thickness of the buffer layer 30 to the upper surface after stopping the supply of the Fe-doping source gas. A designed thickness of the buffer lower layer 31 is, for example, 200 nm or more and 2000 nm or less, and a designed thickness of the buffer upper layer 32 is, for example, 200 nm or more and 1000 nm or less.

Although Fe is added to the buffer lower layer 31, it diffuses to the upper surface of the buffer upper layer 32. Thereby, the buffer layer 30 contains Fe over a range from the buffer lower layer 31 to the buffer upper layer 32. As described later, by measuring the wafer 110 by secondary ion mass spectrometry (SIMS), the distribution of Fe concentration in a thickness direction in the diffusion suppressing part 1 (buffer layer 30, diffusion suppressing layer 40, and channel layer 50) is obtained. In the Fe concentration distribution in the buffer layer 30, the Fe peak concentration exists near the growth thickness at which the supply of Fe-doping source gas is stopped. The Fe peak concentration is referred to as a doping peak concentration C1. Fe is added to the buffer layer 30 so that the doping peak concentration C1 is, for example, preferably 1×10¹⁷ cm⁻³ or more and 1×10¹⁹ cm⁻³ or less.

The diffusion suppressing layer 40 is formed on the buffer layer 30 by, for example, growing an InGaN layer to a designed thickness of 1 nm or more and 10 nm or less. For example, the channel layer 50 is formed by growing a GaN layer on the diffusion suppressing layer 40 to a designed thickness of 5 nm or more and 100 nm or less.

The In composition of InGaN constituting the diffusion suppressing layer 40 is set to such a height that the channel layer 50 is substantially free of Fe. As will be described later, the In composition for the channel layer 50 to be substantially free of Fe may vary depending on the Fe concentration of the buffer layer 30. One guideline is more than 15%, preferably more than 16%.

The barrier layer 60 is formed on the channel layer 50 by, for example, growing an AlGaN layer to a designed thickness of 5 nm or more and 80 nm or less. On the barrier layer 60, the cap layer 70 is formed by, for example, growing a GaN layer to a designed thickness of 10 nm or less, if necessary. The wafer 110 is manufactured in the manner described above.

Thereafter, the HEMT 100 is manufactured by forming the electrode 120 (source electrode 121, gate electrode 122, and drain electrode 123) and other members such as an insulating film as necessary on the wafer 110 using an appropriately known technique related to HEMT manufacturing.

Hereinafter, the diffusion suppressing part 1 will be further described with reference to SIMS measurement results (SIMS profiles) for the sample of an embodiment and the sample of a comparative embodiment. By performing SIMS measurement to the samples of the embodiment and the comparative embodiment, the Fe concentration, Ga amount, Al amount, and In amount in the thickness direction were obtained. The Fe concentration distribution, Ga content distribution, Al content distribution, and In content distribution were measured using a magnetic field type SIMS device. However, the measurement of the In content distribution for quantifying the In composition was performed using a quadrupole SIMS device (see FIG. 9).

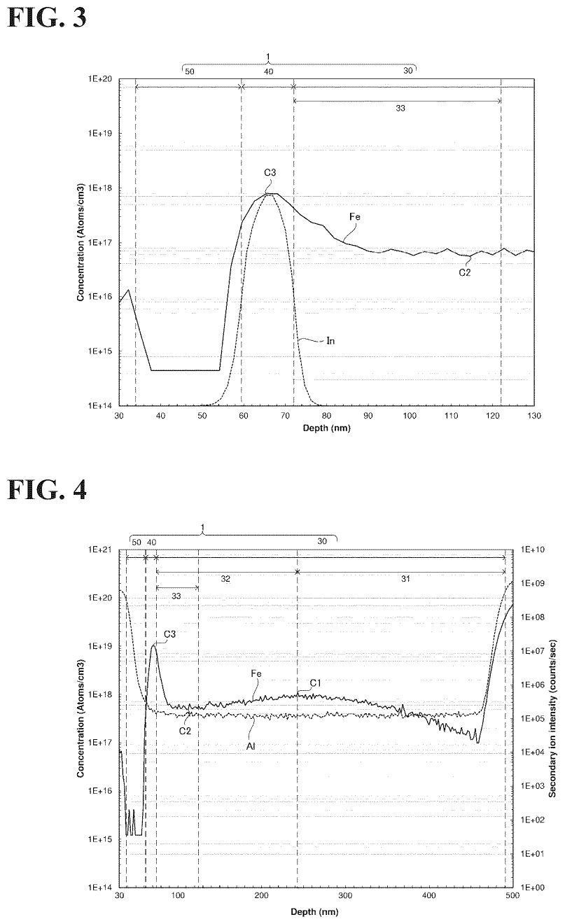

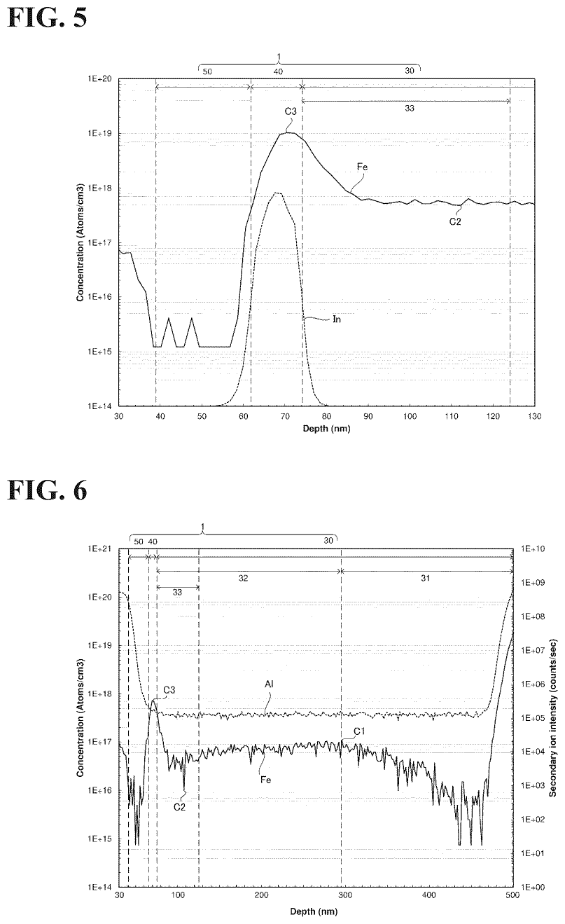

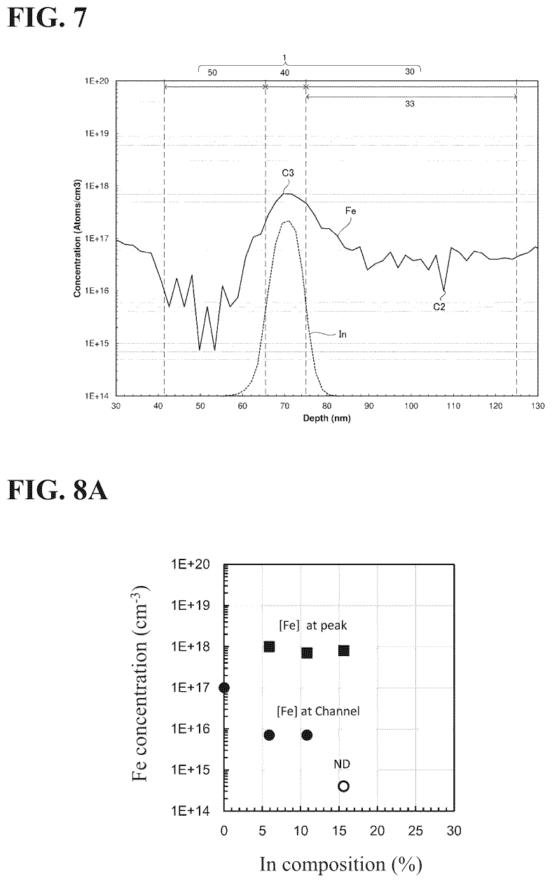

FIGS. 2 and 3 are SIMS profiles of a sample according to a first example of the embodiment, FIGS. 4 and 5 are SIMS profiles of a sample according to a second example of the embodiment, and FIGS. 6 and 7 are SIMS profiles of a sample according to the comparative embodiment. FIGS. 2, 4, and 6 are overall SIMS profiles of the diffusion suppressing part 1 in the HEMT 100, including an entire thickness of the buffer layer 30. FIG. 3, FIG. 5, and FIG. 7 are partial SIMS profiles of the diffusion suppressing part 1 in the HEMT 100, showing the vicinity of the diffusion suppressing layer 40.

FIGS. 2, 4, and 6 show the Fe concentration distribution as well as the Al amount distribution. The Fe concentration distribution is shown by a solid line, and the Al amount distribution is shown by a dotted line. In FIGS. 2, 4, and 6, the left axis shows the Fe concentration, and the right axis shows the intensity of secondary ions related to Al.

FIGS. 3, 5, and 7 show the Fe concentration distribution as well as the In amount distribution. The Fe concentration distribution is shown by a solid line, and the In amount distribution is shown by a dotted line. In FIGS. 3, 5, and 7, the left axis shows the Fe concentration. FIG. 3, FIG. 5, and FIG. 7 show the shape of the In amount distribution, and the In amount is shown in arbitrary units. Here, the In amount is shown on a linear scale rather than a logarithmic scale. A calculation method based on SIMS measurement of the In composition will be described later with reference to FIG. 9.

The nucleation layer 20 comprises AlN, and the buffer layer 30 comprises GaN. A thickness position where the Al amount on the buffer layer 30 side is reduced to half of the peak Al amount in the nucleation layer 20, is defined as an interface between the nucleation layer 20 and the buffer layer 30.

The buffer layer 30 comprises GaN, the diffusion suppressing layer 40 comprises InGaN, and the channel layer 50 comprises GaN. The thickness position where the In amount on the buffer layer 30 side is reduced to half of the peak In amount in the diffusion suppressing layer 40, is defined as an interface between the buffer layer 30 and the diffusion suppressing layer 40. The thickness position where the In amount on the channel layer 50 side is reduced to half of the peak In amount in the diffusion suppressing layer 40, is defined as an interface between the diffusion suppressing layer 40 and the channel layer 50.

The channel layer 50 comprises GaN, and the barrier layer 60 comprises AlGaN. The thickness position where the Al amount on the channel layer 50 side is reduced to half of the peak Al amount in the barrier layer 60, is defined as an interface between the channel layer 50 and the barrier layer 60.

The Fe concentration distribution in the buffer layer 30 is such that the Fe peak concentration (doping peak concentration C1) exists near the growth thickness where the supply of the Fe-doping source gas is stopped. In the buffer layer 30, a lower side is defined as a buffer lower layer 31, and an upper side is defined as a buffer upper layer 32, with the thickness position where the Fe doping peak concentration C1 exists as a boundary. A region with a thickness of 50 nm on the buffer layer 30 side from the interface between the buffer layer 30 and the diffusion suppressing layer 40, is defined as a near-interfacial region 33 between the buffer layer 30 and the diffusion suppressing layer 40.

The thickness of each layer can be obtained based on an interface position and a boundary position obtained by the SIMS measurement. The thickness of each layer obtained by such a SIMS measurement may not match a designed thickness. For example, the thickness of the diffusion suppressing layer 40 obtained by the SIMS measurement tends to be several times thicker than the designed thickness of the diffusion suppressing layer 40. Since it is not possible to know the designed thickness, which is a numerical value assumed at the time of design, from the prepared wafer 110 itself, here, the interface position and the boundary position obtained by the SIMS measurement and the thickness of each layer are used.

Both the first example of the embodiment illustrated in FIGS. 2 and 3 and the comparative embodiment illustrated in FIGS. 6 and 7 show a sample in which Fe is added to the buffer layer 30 with a designed value of the doping peak concentration C1 set as 1×10¹⁷ cm⁻³. However, the first example of the embodiment and the comparative embodiment differ in the In composition of InGaN constituting the diffusion suppressing layer 40. The In designed composition of the diffusion suppressing layer 40 in the comparative embodiment is as low as 10.8%, and the In designed composition of the diffusion suppressing layer 40 in the first example of the embodiment is as high as 15.6%.

The second example of the embodiment illustrated in FIGS. 4 and 5 is a sample in which Fe is added to the buffer layer 30 with a designed value of the doping peak concentration C1 set as 1×10¹⁸ cm⁻³, and a designed In composition of the diffusion suppressing layer 40 is as high as 27.1%.

In the first example and the second example of the embodiment and the comparative embodiment, the distributions of the Fe concentration, Al amount, and In amount obtained by the SIMS measurement have the following similar characteristics. The Al amount decreases from the nucleation layer 20 to the buffer layer 30 and remains approximately constant within the buffer layer 30. The Fe concentration tends to be observed at a high concentration in the nucleation layer 20, and decreases as the Al amount decreases toward the buffer layer 30, and reaches its lowest value near the lower surface of the buffer layer 30.

It is considered that observing a high Fe concentration near the interface between the buffer layer 30 and the nucleation layer 20 is not caused by the addition of Fe to the buffer layer 30, but is caused by containing Al in the nucleation layer 20. Therefore, here, a portion near the interface where the Fe concentration is high originating from the nucleation layer 20 (portion on the nucleation layer 20 side of the lowest value in the Fe concentration distribution) is excluded from the Fe concentration distribution in the buffer layer 30. That is, the Fe concentration distribution on the upper side of the lowest value is defined as the Fe concentration distribution in the buffer layer 30.

The Fe concentration reaches its lowest value near the lower surface of the buffer layer 30, that is, near the lower surface of the buffer lower layer 31, and then increases upward as Fe is added to the buffer lower layer 31, and reaches the doping peak concentration C1 at the upper surface of the buffer lower layer 31.

The Fe concentration decreases upward from the lower surface of the buffer upper layer 32, increases in the near-interfacial region 33, increases toward the diffusion suppressing layer 40 in the near-interfacial region 33, and after this increase, reaches a peak near the interface between the buffer upper layer 32 and the diffusion suppressing layer 40. The Fe concentration at which it starts to increase in the near-interfacial region 33, that is, the lowest value of the Fe concentration in the near-interfacial region 33, is referred to as a near-interfacial lowest concentration C2. The peak Fe concentration near the interface between the buffer upper layer 32 and the diffusion suppressing layer 40 is referred to as an interfacial peak concentration C3.

The Fe concentration decreases toward the channel layer 50 after reaching the interfacial peak concentration C3. The In amount has a peak at approximately a central thickness position of the diffusion suppressing layer 40, and the In amount distribution has a bell shape that is approximately symmetrical between the buffer layer 30 side and the channel layer 50 side.

The Fe concentration measured by SIMS in each sample is as follows. In the first example of the embodiment, the doping peak concentration C1 is 1.54×10¹⁷ cm⁻³, the near-interfacial lowest concentration C2 is 5.47×10¹⁶ cm⁻³, and the interfacial peak concentration C3 is 7.96×10¹⁷ cm⁻³. In the second example of the embodiment, the doping peak concentration C1 is 1.1×10¹⁸ cm⁻³, the near-interfacial lowest concentration C2 is 4.85×10¹⁷ cm⁻³, and the interfacial peak concentration C3 is 1.04×10¹⁹ cm⁻³ In the comparative embodiment, the doping peak concentration C1 is 1.09×10¹⁷ cm⁻³, the near-interfacial lowest concentration C2 is 9.9×10¹⁵ cm⁻³, and the interfacial peak concentration C3 is 7.12×10¹⁷ cm⁻³.

Here, the characteristics of the Fe concentration distribution in the channel layer 50 are significantly different between the first example of the embodiment and the comparative embodiment. In the first example of the embodiment (see especially FIG. 3), after the Fe concentration reaches a lower detection limit (4.44×10¹⁴ cm⁻³) near the lower surface of the channel layer 50, it remains at a low level that reaches the lower detection limit up to the upper surface of the channel layer 50. That is, in the first example of the embodiment, diffusion of Fe into the channel layer 50 originating from the buffer layer 30 is prevented.

In contrast, in the comparative embodiment (see especially FIG. 7), although the Fe concentration is slightly reduced in the channel layer 50, it is not low enough to maintain a stable low level within the thickness range of the channel layer 50. That is, in the comparative embodiment, diffusion of Fe into the channel layer 50 originating from the buffer layer 30 is not prevented.

Both of the first example of the embodiment and the comparative embodiment show a sample in which Fe is added to the buffer layer 30 with a designed value of the doping peak concentration C1 set as 1×10¹⁷ cm⁻³. However, in the first example of the embodiment, diffusion of Fe from the buffer layer 30 to the channel layer 50 is prevented, and in the comparative embodiment, diffusion of Fe from the buffer layer 30 to the channel layer 50 is not prevented. This difference is considered to be because the In composition of the diffusion suppressing layer 40 is higher in the first example of the embodiment (In designed composition 15.6%) than in the comparative embodiment (In designed composition 10.8%).

In the second example of the embodiment (see especially FIG. 5), after the Fe concentration reaches a lower detection limit (1.22×10¹⁵ cm⁻³) near the lower surface of the channel layer 50, it generally maintains a low level that reaches the lower detection limit up to the upper surface of the channel layer 50. In the middle of the thickness of the channel layer 50, there are places where the Fe concentration is slightly high, but these are considered to be noise. Similarly to the first example of the embodiment, in the second example of the embodiment, the diffusion of Fe into the channel layer 50 originating from the buffer layer 30 is prevented. This is considered to be because the In composition of the diffusion suppressing layer 40 is high in the second example of the embodiment (In designed composition 27.1%).

The channel layer 50 of the first example and the second example of the embodiment is characterized in that the Fe concentration continuously reaches the detection limit over a certain thickness range. Therefore, it is concluded that the channel layer 50 does not substantially contain Fe.

The lower detection limit of the Fe concentration may vary slightly in each SIMS measurement. Here, the guideline for a low Fe concentration level that is close to the lower detection limit of Fe concentration, is 2×10¹⁵ cm⁻³ (guideline for a lower Fe concentration is 1.5×10¹⁵ cm⁻³). Further, the guideline for the above-described “certain thickness range” is 3 nm (5 nm as a guideline for a thicker range).

Using these guidelines, it is defined that the channel layer 50 is substantially free of Fe, because in the channel layer 50, the Fe concentration reaches less than 2×10¹⁵ cm⁻³ (preferably less than 1.5×10¹⁵ cm⁻³) continuously over a thickness of at least 3 nm (preferably 5 nm).

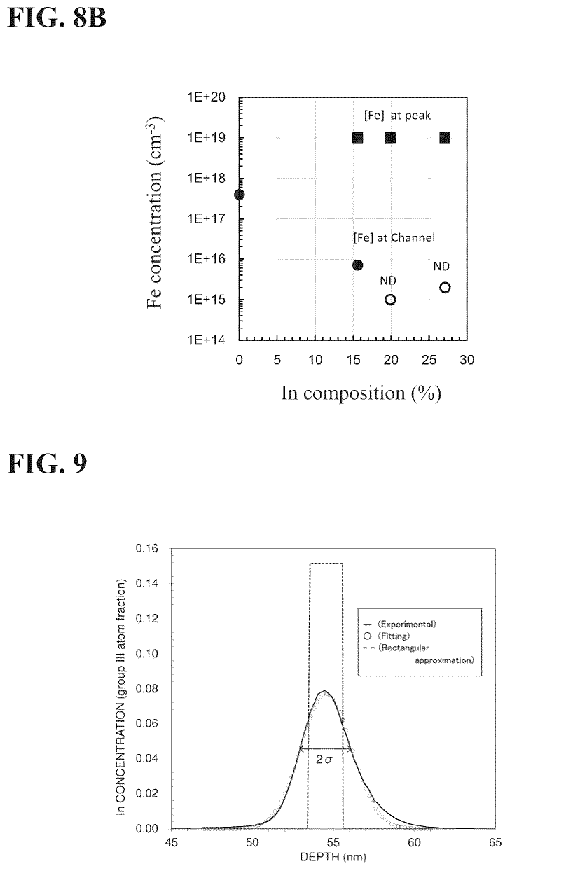

In addition to the samples whose SIMS profiles are shown in FIGS. 2 to 7, various samples were prepared as embodiments and comparative embodiments. FIGS. 8A and 8B are graphs plotting a relationship between the In composition of the diffusion suppressing layer 40 and the Fe concentration in these samples. FIG. 8A shows a sample in which a designed value of the doping peak concentration C1 is 1×10¹⁷ cm⁻³, and FIG. 8B shows a sample in which a designed value of the doping peak concentration C1 is 1×10¹⁸ cm⁻³.

In FIGS. 8A and 8B, the horizontal axis shows the In designed composition, and the vertical axis shows the Fe concentration. The interfacial Fe peak concentration C3 ([Fe] at peak) is shown by a plot of squares, and an average Fe concentration ([Fe] at Channel) in the channel layer 50 is shown by a plot of circles.

The average Fe concentration in the channel layer 50 is defined as an average Fe concentration in the upper 10 nm thickness range, based on the 10 nm thickness position from the interface with the diffusion suppressing layer 40. When the average Fe concentration in the channel layer 50 is less than 3×10¹⁵ cm⁻³, it is judged that Fe is not detected (ND). The case where Fe is not detected is shown by a plot of white circles.

Regarding a measurement shown in FIG. 8A, that is, a measurement where a designed value of the doping peak concentration C1 is 1×10¹⁷ cm⁻³, samples are prepared with In designed compositions of 0% (that is, without the diffusion suppressing layer 40), 5.9%, 10.8%, and 15.6%. The sample with an In designed composition of 10.8% corresponds to the comparative embodiment shown in FIGS. 6 and 7, and the sample with an In designed composition of 15.6% corresponds to the first example of the embodiment shown in FIGS. 2 and 3.

In the sample with the In designed composition of 0%, the characteristic such that the interfacial Fe peak concentration C3 is formed near the interface between the buffer layer 30 and the diffusion suppressing layer 40 and the Fe concentration decreases on the channel layer 50 side, was not observed, while being observed in the sample in which the diffusion suppression layer 40 is provided. Therefore, for the sample with the In designed composition of 0%, the interfacial peak concentration C3 is not plotted, and the average Fe concentration in the channel layer 50 is 1×10¹⁷ cm⁻³, which is about the same as a designed value of the doping peak concentration C1.

The interfacial Fe peak concentrations C3 in samples with In designed compositions of 5.9%, 10.8%, and 15.6% are 1×10¹⁸ cm⁻³, 7×10¹⁷ cm⁻³, and 8×10¹⁷ cm⁻³, and the average Fe concentrations in the channel layer 50 are 7×10¹⁵ cm⁻³, 7×10¹⁵ c⁻³, and 4×10¹⁴ cm⁻³, respectively.

In samples with In designed compositions of 5.9%, 10.8%, and 15.6%, although the interfacial Fe peak concentration C3 is about the same, the result shows that Fe is not detected in the channel layer 50 by increasing the In designed composition to 15.6%. It is judged that Fe is not detected based on the average Fe concentration in the channel layer 50 of the sample with an In designed composition of 15.6% (the first example of the embodiment). This judgment is consistent with a judgment that Fe is not substantially contained based on the distribution shape of the SIMS profile as described above.

For the measurement illustrated in FIG. 8B, that is, the measurement in which the designed value of the doping peak concentration C1 is 1×10¹⁸ cm⁻³, samples with In designed compositions of 0% (that is, without the diffusion suppressing layer 40), 15.6%, 19.9%, and 27.1% are prepared. A sample with an In designed composition of 27.1% corresponds to the second example of the embodiment illustrated in FIGS. 4 and 5.

For the sample with an In designed composition of 0%, the interfacial peak concentration C3 is not plotted, and the average Fe concentration in the channel layer 50 is 4×10¹⁷ cm⁻³, which is slightly lower than the designed value of the doping peak concentration C1.

The interfacial Fe peak concentrations C3 in samples with In designed compositions of 15.6%, 19.9%, and 27.1% are 1×10¹⁹ cm⁻³, 1×10¹⁹ cm⁻³, and 1×10¹⁹ cm⁻³ respectively, and the average Fe concentrations in the channel layer 50 are 7×10¹⁵ cm⁻³, 1×10¹⁵ cm⁻³, and 2×10¹⁵ cm⁻³ respectively.

The interfacial Fe peak concentration C3 is similar in samples with In designed compositions of 15.6%, 19.9%, and 27.1%, and the result shows that Fe is not detected in the channel layer 50 by increasing the In designed composition to 19.9% and 27.1%. It is judged that Fe is not detected based on the average Fe concentration in the channel layer 50 of a sample with an In designed composition of 27.1% (second example of the embodiment). This judgment is consistent with the judgment that Fe is not substantially contained based on the distribution shape of the SIMS profile as described above.

A sample with an In designed composition of 19.9% is referred to as a third example of the embodiment. Also in the sample of the third example of the embodiment, it is judged that Fe is not substantially contained based on the distribution shape of the SIMS profile, similar to the samples of the first and second embodiments, and the judgment based on the average Fe concentration and the judgment based on the distribution shape of the SIMS profile are consistent.

As explained above, by increasing the In composition in the diffusion suppressing layer 40, Fe is prevented from diffusing into the channel layer 50 originating from the buffer layer 30. The In composition required to prevent the diffusion of Fe into the channel layer 50 varies depending on the Fe concentration added to the buffer layer 30, more specifically, the Fe concentration near the interface between the buffer layer 30 and the diffusion suppressing layer 40 (interfacial peak concentration C3 or near-interfacial lowest concentration C2). Accordingly, it is preferable that the higher the Fe concentration of the buffer layer 30, the higher the In composition of the diffusion suppressing layer 40.

In other words, it is preferable that the In composition of the diffusion suppressing layer 40 is set appropriately high according to the Fe concentration of the buffer layer 30 so as to prevent Fe from diffusing into the channel layer 50. A specific guideline for the In composition of the diffusion suppressing layer 40 is more than 15%, preferably more than 16%.

From a viewpoint of preventing the diffusion of Fe into the channel layer 50, an upper limit of the In composition of the diffusion suppressing layer 40 is not particularly limited, and as a guideline, a value of (at least) 31.4% can be given. This is because good results were obtained with a sample with an In designed composition of 31.4% in measurements for the HEMT characteristics described below.

The In designed composition is a numerical value assumed at the time of design, and cannot be known from the prepared wafer 110 itself. However, it is considered that the In composition close to the designed composition is achieved in the appropriately prepared diffusion suppressing layer 40. Here, a method of calculating the In composition based on SIMS measurement will be described.

FIG. 9 is a SIMS profile illustrating the In content distribution of the diffusion suppressing layer 40 with a designed In composition of 15.6% and a designed thickness of 2 nm. The left axis shows the In composition. As described above, the In amount distribution for determining the In composition is measured using a quadrupole SIMS device.

A total amount of In contained in the diffusion suppressing layer 40 corresponds to a total area of the In amount distribution. In this method, first, the In amount distribution is fitted with a Gaussian distribution. An actually measured (experimental) In amount distribution is shown by a solid line, and a fitted Gaussian distribution is shown by a plot of circles.

Next, an area of the Gaussian distribution is calculated using the fitted parameters of the Gaussian distribution. In this example, the fitted Gaussian distribution has a height of 0.0773, a center value of 54.6, a Gaussian width of 1.56, and an area of 0.303.

A rectangle having an area equal to the area of the fitted Gaussian distribution and a width of 2 nm in designed thickness is indicated by a dotted line. The height of the rectangle is considered to indicate the In composition in an embodiment with the diffusion suppressing layer 40 having a uniform composition within a designed thickness range of 2 nm. In this example, the height of the rectangle is 15.1% (area 0.303/thickness 2 nm), which is approximately equal to 15.6% that is the In designed composition.

When the designed thickness is unknown, the thickness of the diffusion suppressing layer 40 measured by transmission electron microscopy is treated as the designed thickness, and by dividing the area of the fitted Gaussian distribution by this thickness, the In composition based on the SIMS measurement can be calculated.

Hereinafter, more detailed characteristics of the diffusion suppressing unit 1 will be exemplarily described. As described above, by using the diffusion suppressing layer 40 of this embodiment, the high-resistance impurity originating from the buffer layer 30 is prevented from diffusing into the channel layer 50, and thereby, electrical insulation can be improved by increasing the concentration of the high-resistance impurity in the region 33 near the interface of the buffer layer 30 (that is, the region near the upper surface of the buffer layer 30) while suppressing a decrease in the conductivity of the channel layer 50. In the example of the HEMT 100, leakage current of the HEMT flowing through the buffer layer 30 can be suppressed.

The near-interfacial lowest concentration C2 (the lowest value of the high-resistance impurity concentration in the near-interfacial region 33) is a concentration slightly lower than the doping peak concentration C1. The doping peak concentration C1 is, for example, preferably 1×10¹⁷ cm⁻³ or more, and the near-interfacial lowest concentration C2 is, for example, preferably 2×10¹⁶ cm⁻³ or more.

In order to make the near-interfacial lowest concentration C2 high, it is preferable that the near-interfacial lowest concentration C2 not be excessively lowered from the doping peak concentration C1. The ratio of the near-interfacial lowest concentration C2 to the doping peak concentration C1 (C2/C1) is preferably, for example, 1/30 or more (approximately 0.033 or more), more preferably, 1/10 or more (0.1 or more). The doping peak concentration C1 can be said to be a peak concentration higher than the near-interfacial lowest concentration C2, which exists in a region on more lower surface side of the buffer layer 30 than the near-interfacial region 33.

In the first example of the embodiment, the doping peak concentration C1 is 1.54×10¹⁷ cm⁻³, and the near-interfacial lowest concentration C2 is 5.47×10¹⁶ cm⁻³. In the second example of the embodiment, the doping peak concentration C1 is 1.1×10¹⁸ cm⁻³ and the near-interfacial lowest concentration C2 is 4.85×10¹⁷ cm⁻³, and the ratio (C2/C1) of the near-interfacial lowest concentration C2 to the doping peak concentration C1 is 0.355 in the first example of the embodiment, and 0.441 in the second example of the embodiment.

As the buffer upper layer 32 becomes thicker, the near-interfacial lowest concentration C2 decreases from the doping peak concentration C1. In order not to excessively lower the near-interfacial lowest concentration C2 from the doping peak concentration C1, the thickness of the buffer upper layer 32 is preferably thin. As a guideline for the thinness of the buffer upper layer 32, for example, the thickness of the buffer upper layer 32 is thinner than the thickness of the buffer lower layer 31. As a guideline for the thinness of the buffer upper layer 32, for example, the buffer upper layer 32 has a thickness of 250 nm or less. Here, the thickness of the buffer lower layer 31 can defined as the thickness of a portion of the buffer layer 30 from the lower surface of the buffer layer 30 to a thickness position where the doping peak concentration C1 exists. Further, the thickness of the buffer upper layer 32 can be defined as the thickness of the buffer layer 30 from the thickness position where the doping peak concentration C1 exists to the interface with the diffusion suppressing layer 40.

The suppression of the diffusion of the high-resistance impurity into the channel layer 50 can also be evaluated by comparing the near-interfacial lowest concentration C2 with the high-resistance impurity concentration in the channel layer 50. For example, as a characteristic, the high-resistance impurity concentration on the upper surface of the channel layer 50 is lower than the near-interfacial lowest concentration C2.

The interfacial peak concentration C3 tends to be approximately 15 to 20 times higher than the near-interfacial lowest concentration C2 as seen from the first and second embodiments as described below. As the near-interfacial lowest concentration C2 increases, the interfacial peak concentration C3 also increases. By setting the near-interfacial lowest concentration C2 to, for example, preferably 2×10¹⁶ cm⁻³ or more, the interfacial peak concentration C3 becomes, for example, preferably 3×10¹⁷ cm⁻³ or more.

In the first example of the embodiment, the interfacial peak concentration C3 is 7.96×10¹⁷ cm⁻³, and the ratio to the near-interfacial lowest concentration C2 (5.47×10¹⁶ cm⁻³) is about 15 times. In the second example of the embodiment, the interfacial peak concentration C3 is 1.04×10¹⁹ cm⁻³, and the ratio to the near-interfacial lowest concentration C2 (4.85×10¹⁷ cm⁻³) is about 20 times.

The diffusion suppressing layer 40 according to this embodiment has high barrier properties against the high-resistance impurity. Thereby, even when the interfacial peak concentration C3 is 3×10¹⁷ cm⁻³ or more, the high-resistance impurity concentration in the channel layer 50 can be 2×10¹⁵ cm⁻³ or less, which is a guideline for a low Fe concentration level.

That is, the ratio of 2×10¹⁵ cm⁻³ to the interfacial peak concentration C3 (2×10¹⁵/C3) can be 1/150 or less (approximately 0.0067 or less), which is a reduction ratio when the high-resistance impurity concentration decreases from the interfacial peak concentration C3 (3×10¹⁷ cm⁻³ or more) to 2×10¹⁵ cm⁻³.

In the first example of the embodiment, the ratio of 2× 10¹⁵ cm⁻³ to the interfacial peak concentration C3 (7.96×10¹⁷ cm⁻³) is 0.00251. In the second example of the embodiment, the ratio of 2× 10¹⁵ cm⁻³ to the interfacial peak concentration C3 (1.04×10¹⁹ cm⁻³) is 0.000192.

Further, the diffusion suppressing layer 40 according to this embodiment has a function of rapidly decreasing the concentration of the high-resistance impurity upward in the thickness direction. As seen in the first example and the second example of the embodiment as described below, a rapid decrease in the high-resistance impurity concentration typically occurs within a thickness of about 12 nm. On the assumption that a decrease in the high-resistance impurity concentration from the interfacial peak concentration C3 (3×10¹⁷ cm⁻³ or more) to 2×10¹⁵ cm⁻³ occurs within a thickness of 12 nm, an average decreasing slope in this case is 2.5×10¹⁶ cm⁻³/nm or more.

In the first example of the embodiment, the interfacial peak concentration decreases from C3 (7.96×10¹⁷ cm⁻³) to 2×10¹⁵ cm⁻³ over a thickness of 11.2 nm, and an average decreasing slope at this time is 7.10×10¹⁶ cm⁻³/nm. In the second example of the embodiment, the interfacial peak concentration decreases from C3 (1.04×10¹⁹ cm⁻³) to 2×10¹⁵ cm⁻³ over a thickness of 13.2 nm, and the average decreasing slope at this time is 7.88×10¹⁷ cm⁻³/nm.

When the ratio of the near-interface concentration C2 to the doping peak concentration C1 is large, for example, 1/10 or more, that is, when the near-interfacial concentration C2 does not decrease much from the doping peak concentration C1, the interfacial peak concentration C3 is higher than the doping peak concentration C1. Further, as the interface between the buffer layer 30 and the diffusion suppressing layer 40 is located near the interfacial peak concentration C3, the high-resistance impurity concentration in the buffer layer 30 reaches its highest value at the interface with the diffusion suppressing layer 40. The SIMS profiles of the first and second examples of the embodiments exhibit such an aspect.

In the SIMS profiles of the first and second examples of the embodiment, the interfacial peak concentration C3 is located slightly on the diffusion suppressing layer 40 side from the interface between the buffer layer 30 and the diffusion suppressing layer 40, that is, within the diffusion suppressing layer 40. Accordingly, the interface between the buffer layer 30 and the diffusion suppressing layer 40 is located in the middle of a slope where the high-resistance impurity concentration increases toward the diffusion suppressing layer 40 in the near-interfacial region 33, and at this interface, the high-resistance impurity concentration in the buffer layer 30 reaches its highest value.

Due to errors in SIMS measurement, the interfacial peak concentration C3 may be located slightly on the buffer layer 30 side from the interface between the buffer layer 30 and the diffusion suppressing layer 40, that is, within the buffer layer 30. In such a case, the interface between the buffer layer 30 and the diffusion suppressing layer 40 is located slightly above the thickness position of the interfacial peak concentration C3, at a thickness position where the high-resistance impurity concentration is slightly lower than the interfacial peak concentration C3. However, even in such a case, since the interface between the buffer layer 30 and the diffusion suppressing layer 40 is located near the interfacial peak concentration C3, it can be said that the high-resistance impurity concentration in the buffer layer 30 reaches its highest value at the interface with the diffusion suppressing layer 40.

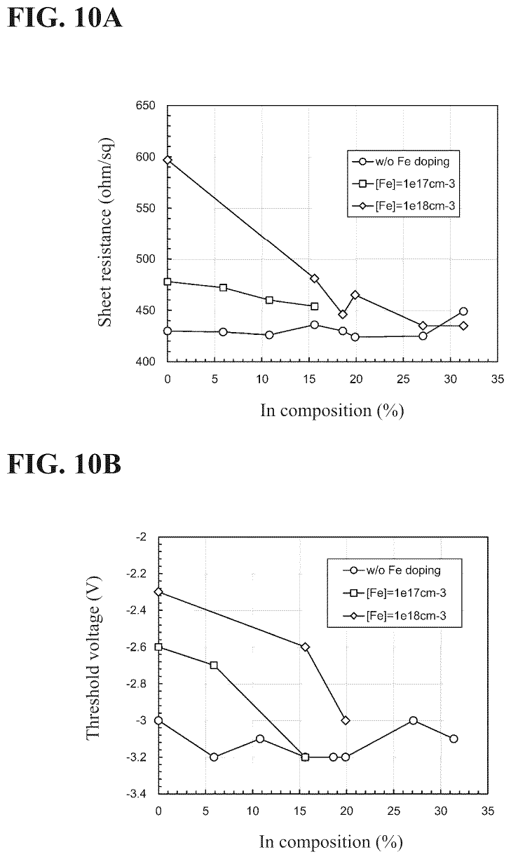

Hereinafter, the characteristics of the HEMT 100 including the diffusion suppressing part 1 will be exemplified. Specifically, characteristics regarding a sheet resistance and a threshold voltage of the HEMT 100 will be described. FIG. 10A is a graph plotting a relationship between the In composition of the diffusion suppressing layer 40 and the sheet resistance in the HEMT 100, in which the horizontal axis shows the In design composition, and the vertical axis shows the sheet resistance. FIG. 10B is a graph plotting a relationship between the In composition of the diffusion suppressing layer 40 and a threshold voltage in the HEMT 100, in which the horizontal axis shows the In design composition, and the vertical axis shows the threshold voltage.

In FIGS. 10A and 10B, an embodiment with Fe not added (w/o Fe doping) is shown by a plot of circles, and an embodiment with a designed value of the Fe doping peak concentration C1 of 1×10¹⁷ cm⁻³ ([Fe]=1e17 cm−3) is shown by a plot of squares, and an embodiment with a designed value of the Fe doping peak concentration C1 of 1×10¹⁸ cm⁻³ ([Fe]=1e18 cm⁻³) is shown by a plot of diamonds.

In each of the embodiment with Fe not added, the embodiment with a designed value of Fe doping peak concentration C1 of 1×10 cm (hereinafter referred to as “Fe concentration 1×10¹⁷ cm⁻³”), and the embodiment with a designed value of the Fe doping peak concentration C1 of 1×10¹⁸ cm⁻³ (hereinafter referred to as “Fe concentration 1×10¹⁸ cm⁻³”), samples with various In design compositions of the diffusion suppression layer 40 were prepared. The values of the In designed composition illustrated in FIG. 10A are 0% (that is, without the diffusion suppressing layer 40), 5.9%, 10.8%, 15.6%, 18.6%, and 19.9. %, 27.1%, and 31.4%.

Here, in an embodiment with the Fe concentration of 1×10¹⁷ cm⁻³, the interfacial peak concentration C3 corresponds to, for example, 3×10¹⁷ cm⁻³ or more (or the near-interfacial lowest concentration C2 corresponds to, for example, 2×10¹⁶ cm⁻³ or more). In an embodiment with the Fe concentration of 1×10¹⁸ cm⁻³, the interfacial peak concentration C3 corresponds to, for example, 3×10¹⁸ cm⁻³ or more. (or the near-interfacial lowest concentration C2 corresponds to, for example, 2×10¹⁷ cm⁻³ or more).

In the sample with Fe not added and with an In design composition of 0% (that is, a HEMT in which the diffusion suppressing layer 40 is omitted and the buffer layer 30 is free of high-resistance impurity), a sheet resistance (hereinafter referred to as a reference sheet resistance) and a threshold voltage (hereinafter referred to as a reference threshold voltage) are evaluation standards.

Characteristics related to the sheet resistance will be described with reference to FIG. 10A. In the embodiment with Fe not added, even when the In composition of the diffusion suppressing layer 40 is increased, the sheet resistance does not particularly change from the reference sheet resistance. That is, providing the diffusion suppressing layer 40 comprising a group III nitride containing In does not particularly change the sheet resistance.

In the embodiments with Fe added (an embodiment with the Fe concentration of 1×10¹⁷ cm⁻³ and an embodiment with the Fe concentration of 1×10¹⁸ cm⁻³), the sheet resistance is significantly higher than the reference sheet resistance in the sample with an In design composition of 0%. Then, in the embodiment with the Fe concentration of 1×10¹⁸ cm⁻³, the sheet resistance is significantly higher than in the embodiment with the Fe concentration of 1×10¹⁷ cm⁻³. This is considered to be because Fe originating from the buffer layer 30 diffused directly into the channel layer 50 without passing through the diffusion suppressing layer 40, resulting in a decrease in the conductivity of the channel layer 50.

In the embodiments in which Fe is added (an embodiment with the Fe concentration of 1×10¹⁷ cm⁻³ and an embodiment with the Fe concentration of 1×10¹⁸ cm⁻³), in each case, as the In composition of the diffusion suppressing layer 40 becomes higher, the sheet resistance becomes lower and approaches the reference sheet resistance. This is considered to be because the increase in the In composition of the diffusion suppressing layer 40 increases the effect of suppressing the diffusion of Fe into the buffer layer 30, thereby suppressing the decrease in conductivity of the channel layer 50.

The reference sheet resistance is 430 ohm/sq. In the samples with an In design composition of 0% in an embodiment with a Fe concentration of 1×10¹⁷ cm⁻³ and an embodiment with a Fe concentration of 1×10¹⁸ cm⁻³, the sheet resistances are 478 ohm/sq and 597 ohm/sq, respectively. From a viewpoint of suppressing a fluctuation in the sheet resistance, for example, the sheet resistance that is less than 1.1 times the reference sheet resistance (in this example, less than 473 ohm/sq) is judged to be a good sheet resistance.

From FIG. 10A, it is found that even in an embodiment with the Fe concentration of 1×10¹⁷ cm⁻³ (more specifically, the interfacial peak concentration C3 of 3×10¹⁷ cm⁻³ or more, or the near-interfacial lowest concentration C2 of 2×10¹⁶ cm⁻³ or more), further, even in an embodiment with the Fe concentration of 1×10¹⁸ cm⁻³ (more specifically, an embodiment with the interfacial peak concentration C3 of 3×10¹⁸ cm⁻³ or more, or the near-interfacial lowest concentration C2 of 2×10¹⁷ cm⁻³ or more), the sheet resistance can be less than 1.1 times the reference sheet resistance by increasing the In composition of the diffusion suppressing layer 40.

Characteristics regarding a threshold voltage will be described with reference to FIG. 10B. In the embodiment with Fe not added, even when the In composition of the diffusion suppressing layer 40 is increased, the threshold voltage does not particularly change from the reference threshold voltage. That is, providing the diffusion suppressing layer 40 comprising a group III nitride containing In does not particularly change the threshold voltage.

In the embodiments with Fe added (an embodiment with the Fe concentration of 1×10¹⁷ cm⁻³ and an embodiment with the Fe concentration of 1×10¹⁸ cm⁻³), the magnitude of the threshold voltage is significantly smaller than the magnitude of the reference threshold voltage in the sample with an In design composition of 0%, and in the embodiment with the Fe concentration of 1×10¹⁸ cm⁻³, the magnitude of the threshold voltage is smaller than that in the embodiment with the Fe concentration of 1×10¹⁷ cm⁻³.

The threshold voltage is a negative voltage for turning off the HEMT 100, and a small magnitude (absolute value) of the threshold voltage means that the threshold voltage is close to 0 V. That is, the smaller magnitude of threshold voltage than the magnitude of the reference threshold voltage means that the HEMT 100 is more easily turned off. This is considered to be because Fe originating from the buffer layer 30 diffused directly into the channel layer 50 without passing through the diffusion suppressing layer 40, resulting in a decrease in the conductivity of the channel layer 50.

In the embodiments with Fe added (the embodiment with the Fe concentration of 1×10¹⁷ cm⁻³ and the embodiment with the Fe concentration of 1×10¹⁸ cm⁻³), in each case, as the In composition of the diffusion suppressing layer 40 increases, the magnitude of the threshold voltage increases so as to approach the magnitude of the reference threshold voltage, that is, increases in a negative voltage direction. This is considered to be because the increase in the In composition of the diffusion suppressing layer 40 increases the effect of suppressing the diffusion of Fe into the buffer layer 30, thereby suppressing the decrease in conductivity in the channel layer 50.

The magnitude of the reference threshold voltage is 3 V. In the samples with an In design composition of 0% in an embodiment with the Fe concentration of 1×10¹⁷ cm⁻³ and in an embodiment with the Fe concentration of 1×10¹⁸ cm⁻³, the magnitudes of the threshold voltages are 2.6V and 2.3V, respectively. From a viewpoint of suppressing the fluctuation in the magnitude of the threshold voltage, for example, a value of more than 0.9 times the magnitude of the reference threshold voltage (in this example, more than 2.7 V) is judged to be a good magnitude of the threshold voltage.

From FIG. 10B, it is found that even in the embodiment with the Fe concentration of 1×10¹⁷ cm⁻³ (more specifically, the interfacial peak concentration C3 of 3×10¹⁷ cm⁻³ or more, or the neat-interfacial lowest concentration C2 of 2×10¹⁶ cm⁻³ or more), further, it is found that even in the embodiment with the Fe concentration of 1×10¹⁸ cm⁻³ (more specifically, the interfacial peak concentration C3 of 3×10¹⁸ cm⁻³ or more, or the neat-interfacial lowest concentration C2 of 2×10¹⁷ cm⁻³ or more), the magnitude of the threshold voltage can be more than 0.9 times the magnitude of the reference threshold voltage by increasing the In composition of the diffusion suppressing layer 40.

The multilayered structure 100 including the diffusion suppressing part 1 according to the embodiment has been described above using HEMT as an example, but the multilayered structure 100 is not limited to application to HEMT. Further, the structure of the diffusion suppressing part 1 is not limited to the above example. For example, the first layer of the diffusion suppressing part 1 is not limited to an epitaxial layer grown on a growth substrate (a buffer layer in the HEMT example), but may be a free-standing substrate comprising a group III nitride (when FIG. 1 represents such an aspect, the focus is on the layered portion of the first layer 30, second layer 40, and third layer 50 that constitute the diffusion suppressing part 1, and other portions are omitted, and the first layer 30 represents a free-standing substrate).

### Preferable Aspects of the Present Invention

Hereinafter, preferable aspects of the present invention will be supplementarily described.

### (Supplementary Description 1)

A group III nitride multilayered structure, including:
a first layer comprising a group III nitride;
a second layer disposed on the first layer and comprising a group III nitride containing In; and
a third layer disposed on the second layer and comprising a group III nitride,
wherein the first layer contains an impurity that makes the group III nitride electrically highly resistive at least in a near-interfacial region, which is a region with a thickness of 50 nm from an interface between the first layer and the second layer,
a concentration of the impurity is lower on a third layer side than on a first layer side interposing the second layer therebetween, and
in the third layer, the concentration of the impurity reaches less than 2×10¹⁵ cm⁻³ continuously over a thickness of at least 3 nm, so that the third layer is substantially free of the impurity.

### (Supplementary Description 2)

The group III nitride multilayered structure according to supplementary description 1, wherein the second layer comprises a group III nitride having an In composition of more than 15%.

### (Supplementary Description 3)

The group III nitride multilayered structure according to supplementary description 1 or 2, wherein a lowest concentration of the impurity in the near-interfacial region is 2×10¹⁶ cm⁻³ or more.

### (Supplementary Description 4)

The group III nitride multilayered structure according to supplementary description 1 or 2,
wherein the concentration of the impurity increases toward the second layer in the near-interfacial region,
after the increase, the concentration of the impurity reaches a first peak concentration; and
a ratio of 2×10¹⁵ cm⁻³ to the first peak concentration is 1/150 or less, which is a reduction ratio when the concentration of the impurity is decreased from the first peak concentration to 2×10¹⁵ cm⁻³.

### (Supplementary Description 5)

The group III nitride multilayered structure according to supplementary description 1 or 2,
wherein the concentration of the impurity increases toward the second layer in the near-interfacial region;
after the increase, the concentration of the impurity reaches a first peak concentration; and
an average decreasing slope when the concentration of the impurity decreases from the first peak concentration to 2×10¹⁵ cm⁻³, is 2.5×10¹⁶ cm⁻³/nm or more.

### (Supplementary Description 6)

The group III nitride multilayered structure according to supplementary description 1 or 2, wherein in the third layer, an average concentration of the impurity in an upper 10 nm thickness range from a thickness position of 10 nm from an interface with the second layer, is less than 3×10¹⁵ cm⁻³.

### (Supplementary Description 7)

The group III nitride multilayered structure according to supplementary description 1 or 2, wherein the concentration of the impurity in an upper surface of the third layer is lower than a lowest concentration of the impurity in the near-interfacial region of the first layer.

### (Supplementary Description 8)

The group III nitride multilayered structure according to supplementary description 1 or 2, wherein the concentration of the impurity in the first layer reaches a highest value at an interface with the second layer.

### (Supplementary Description 9)

The group III nitride multilayered structure according to supplementary description 1 or 2,
wherein a second peak concentration higher than a lowest concentration of the impurity in the near-interfacial region exists in a region on a more lower surface side of the first layer than the near-interfacial region, and
a ratio of the lowest value to the second peak concentration is 1/30 or more.

### (Supplementary Description 10)

The group III nitride multilayered structure according to supplementary description 1 or 2,
wherein a second peak concentration higher than a lowest concentration of the impurity in the near-interfacial region exists in a region on more lower surface side of the first layer than the near-interfacial region; and
a thickness of the first layer from a thickness position where the second peak concentration exists to an interface with the second layer, is thinner than a thickness of the first layer from a lower surface of the first layer to the thickness position where the second peak concentration exists.

### (Supplementary Description 11)

The group III nitride multilayered structure according to supplementary description 1 or 2,
wherein a second peak concentration higher than a lowest concentration of the impurity in the near-interfacial region exists in a region on more lower surface side of the first layer than the near-interfacial region; and
a thickness of the first layer from a thickness position where the second peak concentration exists to an interface with the second layer, is 250 nm or less.

### (Supplementary Description 12)

The group III nitride multilayered structure according to supplementary description 1 or 2,
wherein a concentration of the impurity increases toward the second layer in the near-interfacial region;
after the increase, the concentration of the impurity reaches a first peak concentration;
a second peak concentration higher than a lowest concentration of the impurity in the near-interfacial region exists in a region on a more lower surface side of the first layer than the near-interfacial region; and
the first peak concentration is higher than the second peak concentration.

### (Supplementary Description 13)

The group III nitride multilayered structure according to supplementary description 1 or 2,
wherein the group III nitride multilayered structure is included as part of a high electron mobility transistor, and
the third layer is a channel layer of the high electron mobility transistor.

### (Supplementary Description 14)

The group III nitride multilayered structure according to supplementary description 1 or 2, wherein the first layer is a free-standing substrate comprising a group III nitride.

### (Supplementary Description 15)

The group III nitride multilayered structure according to supplementary description 1 or 2, wherein the impurity is a transition metal (more preferably such as iron, also such as manganese).

### (Supplementary Description 16)

A high electron mobility transistor including:
a first layer comprising a group III nitride;
a second layer disposed on the first layer and comprising a group III nitride containing In; and
a third layer disposed on the second layer, comprising a group III nitride, and being a channel layer of the high electron mobility transistor,
wherein the first layer contains an impurity that makes the group III nitride electrically highly resistive at least in a near-interfacial region, which is a region with a thickness of 50 nm from an interface between the first layer and the second layer,
a concentration of the impurity increases toward the second layer in the near-interfacial region,
after the increase, the concentration of the impurity reaches a first peak concentration of 3×10¹⁷ cm⁻³ or more,
the concentration of the impurity is lower on a third layer side than on a first layer side interposing the second layer therebetween, and
a sheet resistance of the high electron mobility transistor is less than 1.1 times a sheet resistance of a high electron mobility transistor in which the second layer is omitted and the first layer is free of the impurity.

### (Supplementary Description 17)

A high electron mobility transistor including:
a first layer comprising a group III nitride;
a second layer disposed on the first layer and comprising a group III nitride containing In; and
a third layer disposed on the second layer, comprising a group III nitride, and being a channel layer of the high electron mobility transistor,
wherein the first layer contains an impurity that makes the group III nitride electrically highly resistive at least in a near-interfacial region, which is a region with a thickness of 50 nm from an interface between the first layer and the second layer,
a concentration of the impurity increases toward the second layer in the near-interfacial region,
after the increase, the concentration of the impurity reaches a first peak concentration of 3×10¹⁷ cm⁻³ or more,
the concentration of the impurity is lower on a third layer side than on a first layer side interposing the second layer therebetween, and
a magnitude of threshold voltage of the high electron mobility transistor is more than 0.9 times compared to a magnitude of threshold voltage of the high electron mobility transistor in which the second layer is omitted and the first layer is free of the impurity.

### (Supplementary Description 18)

The high electron mobility transistor according to supplementary description 16 or 17, wherein the first peak concentration is 3×10¹⁸ cm⁻³ or more.

1. A group III nitride multilayered structure, comprising:
a first layer comprising a group III nitride;
a second layer disposed on the first layer and comprising a group III nitride containing In; and
a third layer disposed on the second layer and comprising a group III nitride,
wherein the first layer contains an impurity that makes the group III nitride electrically highly resistive at least in a near-interfacial region, which is a region with a thickness of 50 nm from an interface between the first layer and the second layer,
a concentration of the impurity is lower on a third layer side than on a first layer side interposing the second layer therebetween, and
in the third layer, the concentration of the impurity reaches less than 2×10¹⁵ cm⁻³ continuously over a thickness of at least 3 nm, so that the third layer is substantially free of the impurity.

2. The group III nitride multilayered structure according to claim 1, wherein the second layer comprises a group III nitride having an In composition of more than 15%.

3. The group III nitride multilayered structure according to claim 1, wherein a lowest concentration of the impurity in the near-interfacial region is 2×10¹⁶ cm⁻³ or more.

4. The group III nitride multilayered structure according to claim 1,
wherein the concentration of the impurity increases toward the second layer in the near-interfacial region,
after the increase, the concentration of the impurity reaches a first peak concentration; and
a ratio of 2×10¹⁵ cm⁻³ to the first peak concentration is 1/150 or less, which is a reduction ratio when the concentration of the impurity is decreased from the first peak concentration to 2×10¹⁵ cm⁻³.

5. The group III nitride multilayered structure according to claim 1,
wherein the concentration of the impurity increases toward the second layer in the near-interfacial region;
after the increase, the concentration of the impurity reaches a first peak concentration; and
an average decreasing slope when the concentration of the impurity decreases from the first peak concentration to 2×10¹⁵ cm⁻³ is 2.5×10¹⁶ cm⁻³/nm or more.

6. The group III nitride multilayered structure according to claim 1, wherein in the third layer, an average concentration of the impurity in an upper 10 nm thickness range from a thickness position of 10 nm from an interface with the second layer, is less than 3×10¹⁵ cm⁻³.

7. The group III nitride multilayered structure according to claim 1, wherein the concentration of the impurity in an upper surface of the third layer is lower than a lowest concentration of the impurity in the near-interfacial region of the first layer.

8. The group III nitride multilayered structure according to claim 1 wherein the concentration of the impurity in the first layer reaches a highest value at an interface with the second layer.

9. The group III nitride multilayered structure according to claim 1,
wherein a second peak concentration higher than a lowest concentration of the impurity in the near-interfacial region exists in a region on a more lower surface side of the first layer than the near-interfacial region, and
a ratio of the lowest value to the second peak concentration is 1/30 or more.

10. The group III nitride multilayered structure according to claim 1,
wherein a second peak concentration higher than a lowest concentration of the impurity in the near-interfacial region exists in a region on more lower surface side of the first layer than the near-interfacial region; and
a thickness of the first layer from a thickness position where the second peak concentration exists to an interface with the second layer, is thinner than a thickness of the first layer from a lower surface of the first layer to the thickness position where the second peak concentration exists.

11. The group III nitride multilayered structure according to claim 1,
wherein a second peak concentration higher than a lowest concentration of the impurity in the near-interfacial region exists in a region on more lower surface side of the first layer than the near-interfacial region; and
a thickness of the first layer from a thickness position where the second peak concentration exists to an interface with the second layer, is 250 nm or less.

12. The group III nitride multilayered structure according to claim 1,
wherein a concentration of the impurity increases toward the second layer in the near-interfacial region;
after the increase, the concentration of the impurity reaches a first peak concentration;
a second peak concentration higher than a lowest concentration of the impurity in the near-interfacial region exists in a region on a more lower surface side of the first layer than the near-interfacial region; and
the first peak concentration is higher than the second peak concentration.

13. The group III nitride multilayered structure according to claim 1,
wherein the group III nitride multilayered structure is included as part of a high electron mobility transistor, and
the third layer is a channel layer of the high electron mobility transistor.

14. The group III nitride multilayered structure according to claim 1, wherein the first layer is a free-standing substrate comprising a group III nitride.

15. The group III nitride multilayered structure according to claim 1, wherein the impurity is a transition metal.

16. A high electron mobility transistor including:
a first layer comprising a group III nitride;
a second layer disposed on the first layer and comprising a group III nitride containing In; and
a third layer disposed on the second layer, comprising a group III nitride, and being a channel layer of the high electron mobility transistor,
wherein the first layer contains an impurity that makes the group III nitride electrically highly resistive at least in a near-interfacial region, which is a region with a thickness of 50 nm from an interface between the first layer and the second layer,
a concentration of the impurity increases toward the second layer in the near-interfacial region,
after the increase, the concentration of the impurity reaches a first peak concentration of 3×10¹⁷ cm⁻³ or more,
the concentration of the impurity is lower on a third layer side than on a first layer side interposing the second layer therebetween, and
a sheet resistance of the high electron mobility transistor is less than 1.1 times a sheet resistance of a high electron mobility transistor in which the second layer is omitted and the first layer is free of the impurity.

17. A high electron mobility transistor including:
a first layer comprising a group III nitride;
a second layer disposed on the first layer and comprising a group III nitride containing In; and
a third layer disposed on the second layer, comprising a group III nitride, and being a channel layer of the high electron mobility transistor,
wherein the first layer contains an impurity that makes the group III nitride electrically highly resistive at least in a near-interfacial region, which is a region with a thickness of 50 nm from an interface between the first layer and the second layer,
a concentration of the impurity increases toward the second layer in the near-interfacial region,
after the increase, the concentration of the impurity reaches a first peak concentration of 3×10¹⁷ cm⁻³ or more,
the concentration of the impurity is lower on a third layer side than on a first layer side interposing the second layer therebetween, and
a magnitude of threshold voltage of the high electron mobility transistor is more than 0.9 times compared to a magnitude of threshold voltage of the high electron mobility transistor in which the second layer is omitted and the first layer is free of the impurity.

18. The high electron mobility transistor according to claim 16, wherein the first peak concentration is 3×10¹⁸ cm⁻³ or more.

19. The high electron mobility transistor according to claim 17, wherein the first peak concentration is 3×10¹⁸ cm⁻³ or more.
